(19) United States
(12) Patent Application Publication
(10) Pub. No.: US 2011/0164345 A1
(43) Pub. Date: Jul. 7, 2011

(54) METAL-INSULATOR-METAL CAPACITOR AND METHOD FOR MANUFACTURING THE SAME

(75) Inventors: Jinn P. Chu, Taipei (TW); Cheng-Hui Wu, Taipei (TW); Chon-Hsin Lin, Taipei (TW)

(73) Assignee: NATIONAL TAIWAN UNIVERSITY OF SCIENCE & TECHNOLOGY, Taipei (TW)

(21) Appl. No.: 12/779,306

(22) Filed: May 13, 2010

(30) Foreign Application Priority Data
Jan. 7, 2010 (TW) 099100230

(51) Int. Cl. H01G 4/008; B05D 5/12; C23C 14/34

(52) U.S. Cl. 361/305; 427/79; 204/192.15

(57) ABSTRACT

The present invention provides a metal-insulator-metal capacitor, which includes: a substrate, a copper-based bottom electrode overlying the substrate, wherein the copper based bottom electrode is doped with rhenium nitride or ruthenium nitride, a top electrode overlying the copper based bottom electrode, and a capacitor insulator between and adjoining the copper based bottom electrode and the top electrode.

### CROSS REFERENCE TO RELATED APPILCATIONS

This application claims priority of Taiwan Patent Application No. 099100230, filed on Jan. 7, 2010, the entirety of which is incorporated by reference herein.

### BACKGROUND OF THE INVENTION

1. Field of the Invention

The present invention relates to a metal-insulator-metal (MIM) capacitor, and in particular, relates to an MIM capacitor having high thermal stability.

2. Description of the Related Art

Metal-insulator-metal (MIM) capacitors have been widely used in high frequency circuits and analog circuits. Precious metals such as palladium or ruthenium are often used as the electrodes of the MIM capacitors because they are chemically stable and do not oxidize easily. However, precious metals have drawbacks such as high costs, relatively high resistivities, a rough surface resulting from hillock formation during annealing and a relatively larger grain size leading to rapid diffusion of oxygen atoms.

Therefore, an inevitable trend is for next generation electrode materials to use low resistivity metals. Among all the metals, aluminum and copper have relatively low resistivities. Compared to aluminum, copper is a better option as an electrode since it has a much lower resistivity and a higher resistance for electro-migration.

However, oxygen in a capacitor insulator is prone to diffuse into the copper electrode to from copper oxide during high-temperature processes such that conductivity of the copper electrode is significantly reduced. A barrier layer interposed between the copper electrode and the capacitor insulator is thus needed to prevent oxygen from diffusing from the capacitor insulator into the copper electrode. However, adding a barrier layer also means that an additional layer is additionally connected to the capacitor insulator and copper electrode in series. Therefore, integral electrical property, such as capacitance and conductivity, of the MIM capacitor drops off, which decreases the benefits of using copper as an electrode.

To address the above issues, a novel barrierless copper electrode material is needed which may inhibit the formation of copper oxide during high temperature processes.

### BRIEF SUMMARY OF THE INVENTION

One of the broader forms of an embodiment of the present invention involves a metal-insulator metal (MIM) capacitor. The MIM capacitor includes: a substrate; a copper based bottom electrode overlying the substrate, wherein the copper based bottom electrode is doped with rhenium nitride or ruthenium nitride; a top electrode overlying the copper based bottom electrode; and a capacitor insulator between and adjoining the copper based bottom electrode and the top electrode.

Another one of the broader forms of an embodiment of the present invention involves a method for manufacturing a metal-insulator metal (MIM) capacitor. The method includes: providing a substrate; forming a copper based bottom electrode overlying the substrate, wherein the copper based bottom electrode is doped with rhenium nitride or ruthenium nitride; forming a capacitor insulator overlying the top electrode; and forming a top electrode overlying the capacitor insulator.

A detailed description is given in the following embodiments with reference to the accompanying drawings.

### BRIEF DESCRIPTION OF THE DRAWINGS

The present invention can be further understood by reading the subsequent detailed description and examples with references made to the accompanying drawings, wherein:

FIGS. 1 through 4 illustrate cross section views of an MIM capacitor in accordance with one embodiment of the present invention;

FIG. 5 shows resistivities of an MIM capacitor after annealing at various temperatures in accordance with one embodiment of the present invention; and

FIG. 6 shows an x-ray diffraction figure of an MIM capacitor after annealing at various temperatures in accordance with one embodiment of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. These are, of course, merely examples and are not intended to be limited. For example, the formation of a first feature over, above, below, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. The scope of the invention is best determined by reference to the appended claims.

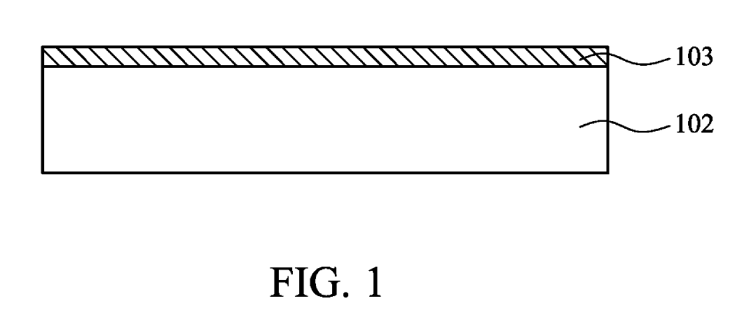

FIGS. 1 through 4 illustrate a method for manufacturing a metal-insulator-metal capacitor according to an embodiment of the present invention. In FIG. 1, a substrate 102 is provided. The substrate 102 may be a silicon substrate. The substrate 102 may alternatively include germanium silicon, gallium arsenic or other suitable semiconductor materials. The substrate 102 may further include other features such as various doped regions, a buried layer and/or an epi layer. Furthermore, the substrate 102 may be a semiconductor on the insulator such as silicon on insulator. In other embodiments, the substrate 102 may include a doped epi layer or a gradient semiconductor layer. In addition, an adhesion layer 103 may be optionally formed on the substrate 102. The adhesion layer 103 may block silicon diffusing from the substrate 102 (provided that substrate contains silicon) to copper to form copper silicide, which ultimately results in increased resistivity. In one preferred embodiment, the adhesion layer 103 may include tantalum nitride (TaN).

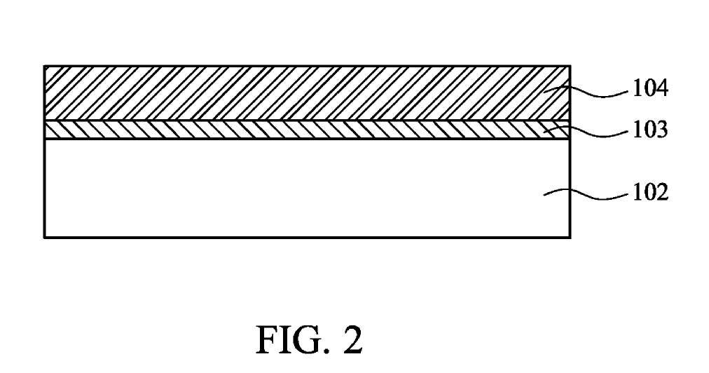

Referring to FIG. 2, illustrated is a copper based bottom electrode 104 formed on the substrate 102. The copper based bottom electrode 104 may be doped with minor rhenium nitride or ruthenium nitride [(Cu(ReNₓ) or Cu(RuNₓ)]. For example, the copper based bottom electrode 104 may include about 0.01 to 10 atomic percent of (a) Re or Ru and (b) N, respectively. The copper based bottom electrode 104 is formed by co-sputtering (i) Cu and (ii) Re or Ru under atmospheres containing N₂ and another inert gas (i.e., He or Ar). A ratio of N₂ to another inert gas may be between about 2% and 30%. Also, the ratio among (a) Cu, (b) N₂ and (c) Re or Ru can be adjusted depending on the design or process requirements. The copper based bottom electrode 104 may have a thickness of between about 1 and 1000 nm. Note that the resistivity of the copper based bottom electrode 104 may reach its lowest value after annealing. In one embodiment, the copper based bottom electrode 104 has a resistivity of between about 4 and 11 μΩ-cm, preferable not exceeding about 6 μΩ-cm, more preferable not exceeding about 4.5 μΩ-cm, after annealing at a temperature of between about 573 K and 873 K.

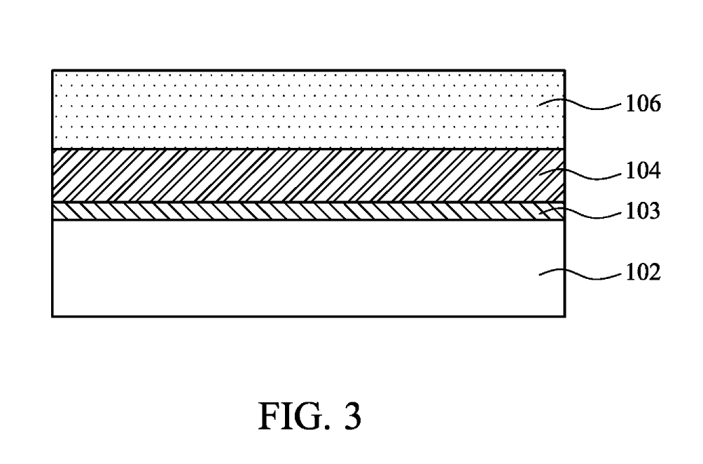

Referring to FIG. 3, illustrated is a capacitor insulator 106 formed on the copper based bottom electrode 104. In one preferred embodiment, the capacitor insulator 106 may include an oxygen-containing insulator which has a dielectric constant more than 4.0. For example, the capacitor insulator 106 may include BaTiO₃, SrTiO₃, BaSrTiO₃, TiO₂, Hf0₂, Al₂O₃, Ta₂O₅, rare earth metal oxides, or the likes or combinations thereof. The capacitor insulator 106 may be formed by chemical vapor deposition, physical vapor deposition, sputtering, magnetic sputtering, ion implantation, atomic layer deposition, pulsed laser deposition or other suitable techniques. The capacitor insulator 106 may have a thickness of between about 1 and 1000 nm. It should be noted that no barrier layer is needed between the capacitor insulator 106 and the copper based bottom electrode 104. Therefore, compared to the conventional MIM capacitor with a barrier layer, the MIM capacitor according to the present invention has a significantly larger capacitance.

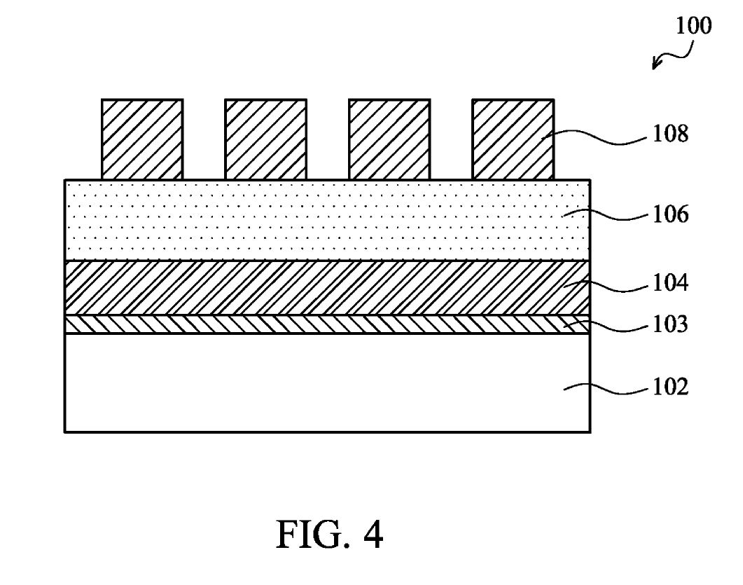

Finally, referring to FIG. 4, illustrated is a top electrode 108 formed on the capacitor insulator 106. The top electrode 108 may be formed of commonly used electrode materials, such as gold, silver, platinum, copper, aluminum or combinations thereof. The top electrode 108 may be formed by chemical vapor deposition, metalorganic chemical vapor deposition, physical vapor deposition, atomic layer deposition, plating, sputtering, magnetic sputtering, pulsed laser deposition or combinations thereof. Thus, completing fabrication of the MIM capacitor. The MIM capacitor thus formed includes a substrate 102, a copper based bottom electrode 104, a top electrode 108, and a capacitor insulator 106 between and adjoining the copper based bottom electrode 104 and the top electrode 108, wherein the copper based bottom electrode 104 is doped with rhenium nitride or ruthenium nitride.

The present invention provides a barrierless copper based electrode, which is doped with rhenium nitride or ruthenium nitride and can effectively block oxygen diffusion from the capacitor insulator. The barrierless copper based electrode can effectively inhibit the formation of copper oxide during high temperature processes, even without the presence of a barrier layer between the capacitor insulator and the copper based electrode. Accordingly, the integral capacitance of the MIM capacitor and the conductivity of the copper based electrode can be maintained, maximizing benefits of the copper based electrode.

### Example 1

A 300 nm thick copper-based bottom electrode was deposited by co-sputtering Cu and Re onto a Si/SiO₂ (150 nm)/TaN (15 nm) stack structure under atmospheres containing 90% Ar and 10% (7×10⁻³ torr of total pressure). The copper based bottom electrode was doped with 0.7 atomic percent of rhenium and 0.06 atomic percent of nitrogen. Next, BaTiO₃ was deposited on the bottom electrode as a capacitor insulator using magnetron sputtering. Then the stack structure of Si/SiO₂/TaN/Cu(ReNₓ)/BaTiO₃ (referred to as “stack structure” hereafter) was annealed under 10⁻¹ torr vacuum at various temperatures ranging from 573K to 923K for 20 mins. The resistivity of copper was measured using the four-point probe method. Finally, a 100 nm Pt film was sputtered onto the stack structure to complete the MIM capacitor.

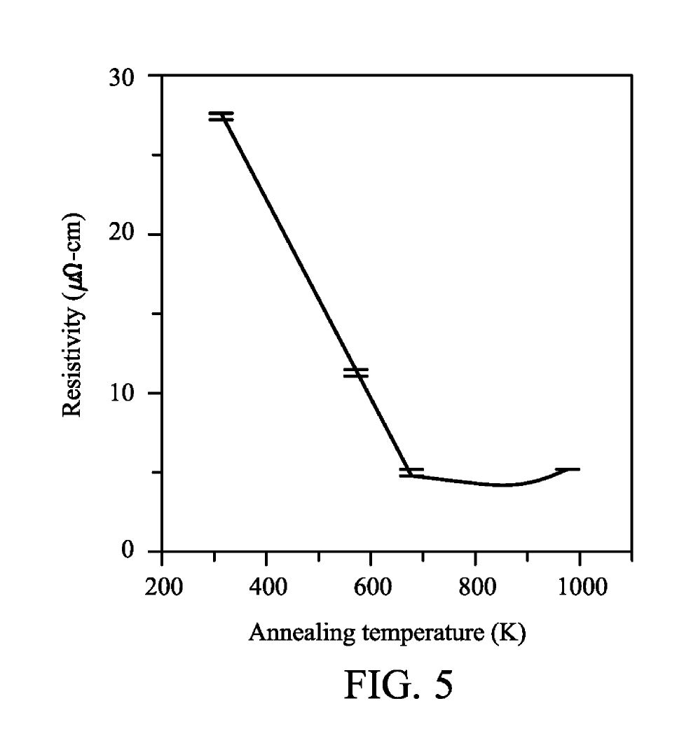

FIG. 5 shows the resistivities of the stack structure of Example 1 after annealing with various temperatures for 20 mins. This figure shows that the copper based electrode doped with rhenium nitride had a resistivity of about 27 μΩ-cm before annealing and the resistivity decreased as the annealing temperature increased. For example, the resistivity reached the lowest value of about 4.5 μΩ-cm after annealing at 873K. Such decrease is due to recrystallization, grain growth, defect annihilation and stress relief for copper at high temperatures (Appl. Phys. Lett. 91, 132109 (2007)). In addition, it was observed that the resistivity was slightly increased at an annealing temperature of up to 923K. The above results suggest that the copper based electrode doped with rhenium nitride has an ultra low resistivity (i.e, 4.5 μΩ-cm) after annealing at a high temperature; especially, compared to commonly used precious metals such as platinum (about 19 μΩ-cm).

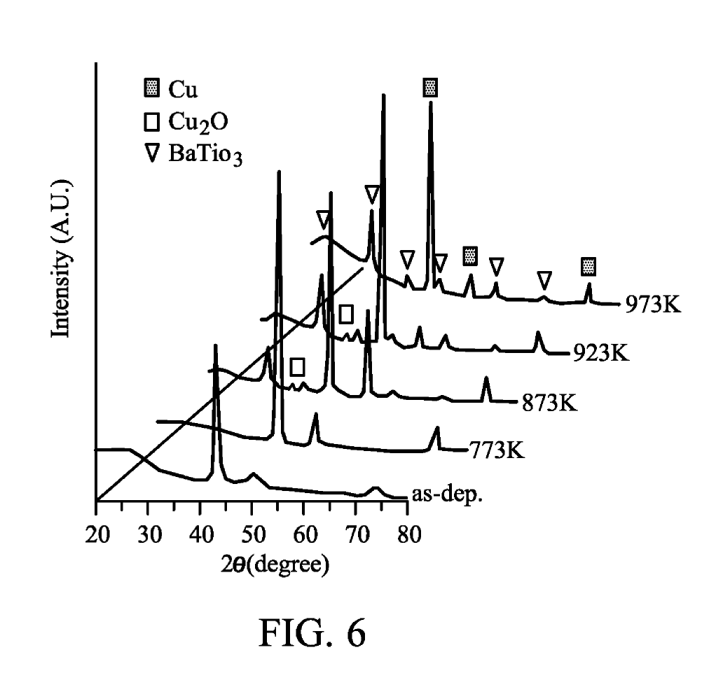

FIG. 6 shows an x-ray diffraction figure of the stack structure of Example 1 after annealing at various temperatures for 20 mins. This figure shows that no copper oxide was formed in the stack structure when the annealing temperature was below 873K. Only a trivial amount of copper oxide (white squares) was formed after annealing at 873K or above, but the Cu Bragg peak (black squares) remained with high intensities, indicating that oxidation was minor. Thus, this confirms the good stability for the copper based electrode. Furthermore, the crystalline BaTiO₃ peaking at around 35° started to appear after 873K, indicating that the transformation from amorphous to crystalline phase occurred.

The SEM image (not shown) of the stack structure of Example 1 shows that all the interfaces between layers in the MIM capacitor were clearly revealed and no reaction compound was evident after annealing at a high temperature. The TEM image (not shown) of the stack structure of Example 1 also shows that only a minor amount of copper oxide was formed and the crystalline copper was still the major phase. Therefore, the electrical property of copper was maintained. Furthermore, no irregular morphology or aggregation resulting from the doped rhenium or nitrogen was observed.

The embodiments of the present invention provide many advantages. By means of doping rhenium nitride or ruthenium nitride into the copper electrode, the MIM capacitor had high thermal stability without the necessity of a barrier layer. Thus, electrical properties, such as capacitance and conductivity, of the MIM capacitor containing the copper based electrode doped with rhenium nitride or ruthenium nitride may be significantly increased.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A metal-insulator-metal (MIM) capacitor, comprising
a substrate;
a copper based bottom electrode overlying the substrate, wherein the copper based bottom electrode is doped with rhenium nitride or ruthenium nitride;
a top electrode overlying the copper based bottom electrode; and
a capacitor insulator between and adjoining the copper based bottom electrode and the top electrode.

2. The metal-insulator-metal capacitor as claimed in claim 1, wherein the copper based bottom electrode comprises about 0.01 to 10 atomic percent of (a) rhenium or ruthenium and (b) nitrogen, respectively.

3. The metal-insulator-metal capacitor as claimed in claim 1, wherein the capacitor insulator comprises BaTiO₃, SrTiO₃, BaSrTiO₃, TiO₂, HfO₂, Al₂O₃, Ta₂O₅, rare earth metal oxides or combinations thereof.

4. The metal-insulator-metal capacitor as claimed in claim 1, wherein the copper based bottom electrode has a resistivity not exceeding about 6 μΩ-cm.

5. The metal-insulator-metal capacitor as claimed in claim 1, further comprising an adhesion layer between the substrate and the copper based bottom electrode.

6. A method for manufacturing a metal-insulator-metal capacitor, comprising:
providing a substrate;
forming a copper based bottom electrode overlying the substrate, wherein the copper based bottom electrode is doped with rhenium nitride or ruthenium nitride;
forming a capacitor insulator overlying the top electrode; and
forming a top electrode overlying the capacitor insulator.

7. The method as claimed in claim 6, wherein the copper based bottom electrode comprises about 0.01 to 10 atomic percent of (a) rhenium or ruthenium and (b) nitrogen, respectively.

8. The method as claimed in claim 6, wherein forming the copper based bottom electrode comprises co-sputtering (a) copper and (b) rhenium or ruthenium under atmospheres containing N₂ and other inert gases.

9. The method as claimed in claim 6, wherein the capacitor insulator comprises BaTiO₃, SrTiO₃, BaSrTiO₃, TiO₂, HfO₂, Al₂O₃, Ta₂O₅, rare earth metal oxides or combinations thereof.

10. The method as claimed in claim 6, wherein the copper based bottom electrode has a resistivity not exceeding about 6 μΩ-cm.

11. The method as claimed in claim 6, further comprising forming an adhesion layer between the substrate and the copper based bottom electrode before forming the copper based bottom electrode.
